(19) United States
(12) Patent Application Publication
(10) Pub. No.: US 2024/0114599 A1
(43) Pub. Date: Apr. 4, 2024

(54) OPTICAL HEATING APPARATUS

(71) Applicant: Ushio Denki Kabushiki Kaisha, Tokyo (JP)

(72) Inventors: Kazumasa YOSHIOKA, Tokyo (JP); Yukio UESHIMA, Tokyo (JP)

(73) Assignee: Ushio Denki Kabushiki Kaisha, Tokyo (JP)

(21) Appl. No.: 18/479,302

(22) Filed: Oct. 2, 2023

(30) Foreign Application Priority Data
Oct. 3, 2022 (JP) 2022-159296

(51) Int. Cl. H05B 3/46

(52) U.S. Cl. CPC H05B 3/46

(57) ABSTRACT

An optical heating apparatus includes: a plurality of heating sources to optically heat a substrate; a plurality of light transmissive containers in which the heating sources are inserted and which transmit light from the heating sources; and a vacuum chamber including a housing having an inside in which the substrate can be placed, the housing having a hole to insert the plurality of light transmissive containers at a position opposed to the substrate placed in the inside, wherein each of the plurality of heating sources has at least one light emitting element, and the plurality of heating sources emit light toward the substrate placed in the vacuum chamber through the plurality of light transmissive containers inserted in the hole and protruding from the housing toward the inside.

### BACKGROUND OF THE INVENTION

### Field of the Invention

The present invention relates to an optical heating apparatus.

### Description of the Related Art

An optical heating apparatus is known which is used to thermally treat a substrate placed in a vacuum chamber by emitting light from a plurality of light emitting elements disposed outside the vacuum chamber.

Patent Document 1 discloses one of such optical heating apparatuses. In the optical heating apparatus disclosed in Patent Document 1, a single large-size quartz window for dividing a vacuum area in a vacuum chamber from a non-vacuum area is disposed between the vacuum chamber and a lamp head having a plurality of light emitting elements and disposed outside the vacuum chamber.

### PRIOR ART DOCUMENT

### Patent Document

Patent Document 1: U.S. Pat. No. 7,509,035

### SUMMARY OF THE INVENTION

The market requires that optical heating apparatuses be further improved. It is an object of the present invention to provide an optical heating apparatus obtained by improving conventional optical heating apparatuses.

One of the major items of improvement for an optical heating apparatus is an increase in irradiance. By increasing irradiance, heating temperature can be increased so that heating time can be reduced. The present inventors have intensively studied, and as a result, have found that the optical heating apparatus disclosed in Patent Document 1 has a limit to an increase in irradiance. This is because, as described in Patent Document 1, the vacuum area and the non-vacuum area are divided by a single large-size quartz window. This quartz window needs to have a large area to divide the vacuum area and the non-vacuum area. Therefore, the quartz window is subjected to a large pressing force caused by a differential pressure between the vacuum area and the non-vacuum area. For this reason, the quartz window is required to have a high pressure capacity so as not to be distorted or broken by the large pressing force. As a result, the single large-size quartz window is thickened to have a high pressure capacity. Such a thick quartz window distances the light emitting elements from the substrate, which results in a reduction in irradiance. Further, such a thick quartz window has a large light transmission loss, which results in a reduction in irradiance.

Therefore, the present inventors have developed an optical heating apparatus shown below.

The optical heating apparatus includes:
a plurality of heating sources to optically heat a substrate;
a plurality of light transmissive containers in which the heating sources are inserted and which transmit light from the heating sources; and
a vacuum chamber including a housing having an inside in which the substrate can be placed, the housing having a hole to insert the plurality of light transmissive containers at a position opposed to the substrate placed in the inside,
wherein each of the plurality of heating sources has at least one light emitting element, and
the plurality of heating sources emit light toward the substrate placed in the vacuum chamber through the plurality of light transmissive containers inserted in the hole and protruding from the housing toward the inside.

The optical heating apparatus has a plurality of light transmissive containers to insert one or more heating sources. Therefore, the plurality of heating sources of the optical heating apparatus are dispersedly disposed in the plurality of light transmissive containers. Although details will be described later, this makes it possible to reduce the size of each of the light transmissive containers. As a result, the pressure capacity required by each of the light transmissive containers is reduced. Therefore, the thickness of each of the light transmissive containers can be reduced. A reduction in the thickness of each of the light transmissive containers increases irradiance.

Each of the light transmissive containers may have a flange that is in contact with an outer surface of the housing, and
the flange may have a seal to achieve hermetic sealing between the flange and the outer surface.

The respective heating sources may be inserted in the different light transmissive containers. That is, the number of the heating sources inserted in one light transmissive container is one. Such a form of the optical heating apparatus is a developed form of dispersedly disposing a plurality of heating sources in a plurality of light transmissive containers. This reduces the pressure capacity required of each of the light transmissive containers so that the thickness of each of the light transmissive containers can be reduced.

The light emitting element of at least one of the heating sources may be located inside the housing. When the light emitting element is located inside the housing, light emitted from the light emitting element is less likely to be blocked by the housing.

The light emitting element may be a filament.

The optical heating apparatus may include a distance adjuster to adjust a distance between the light emitting element of each of the heating sources and the substrate. By adjusting the distance, irradiance can be increased as a whole while an in-plane irradiance variation is reduced.

The distance adjuster may include a drive unit to displace the light emitting element and a control unit to control the drive unit, and
the control unit may displace the light emitting element according to a separation distance between a center of the substrate and a position on the substrate opposed to the light emitting element.

Each of the light transmissive containers may include a reflector or a light shield to reflect or shield light traveling toward the other light transmissive containers.

The reflector or the light shield may be formed on an inner surface of each of the light transmissive containers.

The optical heating apparatus may include a reflector having a parabolic shape or an elliptical shape to orient light emitted from the light emitting element toward the substrate. This improves the use efficiency of light.

The optical heating apparatus may include a nozzle to supply cooling fluid between the light transmissive containers and the heating sources.

The present invention makes it possible to provide an optical heating apparatus obtained by improving conventional optical heating apparatuses.

### BRIEF DESCRIPTION OF THE DRAWINGS

FIG. 1 is a diagram showing a first embodiment of an optical heating apparatus;

FIG. 2 is an enlarged view of one light transmissive container and its peripheral area;

FIG. 3 is an exploded view of the area shown in FIG. 2;

FIG. 4 is a diagram showing a positional relationship between a plurality of heating sources of the optical heating apparatus and a substrate;

FIG. 5 is a graph showing a relationship between a distance from the central position of a substrate and irradiance;

FIG. 6 is a graph showing a relationship between a distance from the central position of a substrate and irradiance when an in-plane irradiance variation is reduced;

FIG. 7 is a diagram showing a case where distances d1 in the optical heating apparatus are set on a zone-by-zone basis;

FIG. 8 is a diagram for illustrating a major part of a second embodiment of the optical heating apparatus;

FIG. 9 is a diagram for illustrating a major part of a third embodiment of the optical heating apparatus;

FIG. 10 is a diagram for illustrating a major part of a fourth embodiment of the optical heating apparatus;

FIG. 11 is a diagram showing a fifth embodiment of the optical heating apparatus; and

FIG. 12 is a diagram showing a sixth embodiment of the optical heating apparatus.

### DETAILED DESCRIPTION OF THE PREFERRED EMBODIMENTS

Embodiments of the present invention will be described with reference to the drawings. It should be noted that the drawings disclosed herein merely show schematic illustrations except for graphs. Namely, the dimensional ratios on the drawings do not necessarily reflect the actual dimensional ratios, and the dimensional ratios are not necessarily the same between the drawings.

Hereinafter, each of the drawings is described with reference to an XYZ coordinate system. When it is necessary to make a distinction between positive or negative to express a direction herein, the direction is described with a positive or negative sign, such as “+X direction” or “−X direction”. In a case where there is no need to distinguish between positive and negative directions, the direction is simply described as the “X direction”. Namely, in the present specification, in a case where the direction is simply described as the “X direction”, both “+X direction” and “−X direction” are included. The same applies to a Y direction and a Z direction. In the embodiments described below, the direction of gravitational force corresponds to a −Z direction.

### First Embodiment

### [Outline of Optical Heating Apparatus]

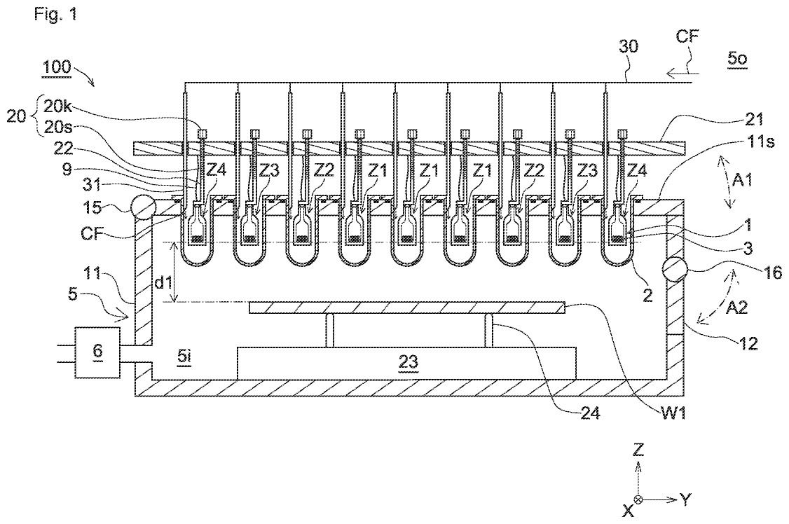

A first embodiment of an optical heating apparatus will be described with reference to FIG. 1. An optical heating apparatus 100 has a plurality of heating sources 1, a plurality of light transmissive containers 2 in which the respective heating sources 1 are inserted and which transmit light from the heating sources 1, and a vacuum chamber 5. Each of the heating sources 1 is a single end-type light generator that emits light mainly in a −Z direction and that has a power feeder 9 extending in a +Z direction. The respective heating sources 1 are disposed inside the light transmissive containers 2. Each of the heating sources 1 includes a light emitting element 3 for optically heating a substrate W1. The substrate W1 is not limited, and may be, for example, a silicon wafer.

In the present embodiment, the heating sources 1 are disposed on the +Z side of the substrate W1, but a positional relationship between the substrate W1 and the heating sources 1 is freely selected. For example, the heating sources 1 may be disposed on the −Z side of the substrate W1. In this case, the heating sources 1 may emit light in the +Z direction. Further, the substrate W1 is not necessarily placed in a horizontal direction. For example, the substrate W1 may be placed so as to stand along an XZ plane. In this case, the heating sources may emit light in a +Y direction or a −Y direction with respect to the substrate W1.

The vacuum chamber 5 is surrounded by a housing 11. The vacuum chamber 5 is connected to a vacuum pump 6 so that an inside Si of the vacuum chamber 5 can be decompressed. A “vacuum area” herein refers to an area whose pressure is reduced from that of a “non-vacuum area”. The atmospheric pressure of the “non-vacuum area” is the atmospheric pressure of an environment in which the optical heating apparatus 100 is disposed. Although details will be described later, the light transmissive containers 2 divide, together with the housing 11, a vacuum area in the inside 5i of the vacuum chamber 5 and a non-vacuum area in an outside 5o of the vacuum chamber 5.

The vacuum chamber 5 has a table 23, on which the substrate W1 can be placed, in the inside 5i thereof. The table 23 has a lift pin 24. The substrate W1 is taken into and out of the vacuum chamber 5 with the use of a transfer arm (not shown). The transfer arm can place the substrate W1 taken into the vacuum chamber 5 on the lift pin 24 and can take out the substrate W1 on the lift pin 24 to the outside 5o of the vacuum chamber 5. FIG. 1 shows a state where the substrate W1 is on the lift pin 24, but the substrate W1 can be placed on the table 23 by letting down the lift pin 24.

The housing 11 has a door 12 to take the substrate W1 into and out of the vacuum chamber 5. The door 12 rotates around a hinge 16. In FIG. 1, the door 12 rotates in a direction A2 along an X axis. However, the door 12 may rotate along a Z axis. The outside 5o on the outside of the door 12 may be a space at atmospheric pressure or a space whose pressure is reduced from atmospheric pressure (e.g., a space in a load-lock chamber).

Although details will be described later, a ceiling 11s of the housing 11 has a hole to insert the plurality of light transmissive containers 2. This hole is located at a position opposed to the substrate W1 placed on the table 23. In the present embodiment, the substrate W1 is placed on the table 23 located on the lower side of the vacuum chamber 5 (−Z direction). The hole is provided on the upper side of the housing 11 (+Z direction), that is, in an area corresponding to the ceiling of the housing 11. That is, in the present embodiment, the hole and the substrate are opposed to each other in the Z direction.

The respective light transmissive containers 2 are inserted into the hole provided in the housing 11 and disposed to protrude from the housing 11 toward the inside 5i of the vacuum chamber 5. This makes it possible to dispose the heating sources 1 in the light transmissive containers 2 to be close to the substrate W1. When the heating sources 1 are closer to the substrate W1, a larger amount of optical energy can be transferred to the substrate W1.

The ceiling 11s of the housing 11 of the present embodiment can be rotationally moved around a hinge 15 in a direction A1 shown in FIG. 1. This makes it possible to open and close the vacuum chamber 5. The light transmissive containers 2 and the heating sources 1 are provided in the ceiling 11s of the openable and closable housing 11, which makes it possible to achieve excellent workability during maintenance and inspection of the heating sources 1 and the light transmissive containers 2.

In the optical heating apparatus 100 of the present embodiment, the respective heating sources 1 are inserted in the different light transmissive containers 2. In other words, the number of the heating sources 1 inserted in one light transmissive container 2 is one. This is one of forms in which the plurality of heating sources of the optical heating apparatus 100 are dispersedly disposed in the plurality of light transmissive containers 2. Such a form in which the heating sources 1 are dispersedly disposed in the plurality of light transmissive containers 2 makes it possible to reduce the size of each of the light transmissive containers 2. The light transmissive containers 2 receive, from the non-vacuum area on the outside of the vacuum chamber, a pressing force corresponding to a differential pressure between the vacuum area and the non-vacuum area. When the size of each of the light transmissive containers 2 is small, the pressing force received by each of the light transmissive containers 2 is low. When the pressing force is low, the pressure capacity required of each of the light transmissive containers 2 is low, which makes it possible to reduce the thickness of each of the light transmissive containers 2. When the thickness of each of the light transmissive containers 2 is reduced, there are advantages that distances between each of the heating sources 1 and the substrate W1 can be reduced and that light transmission loss caused by the light transmissive containers 2 can be reduced.

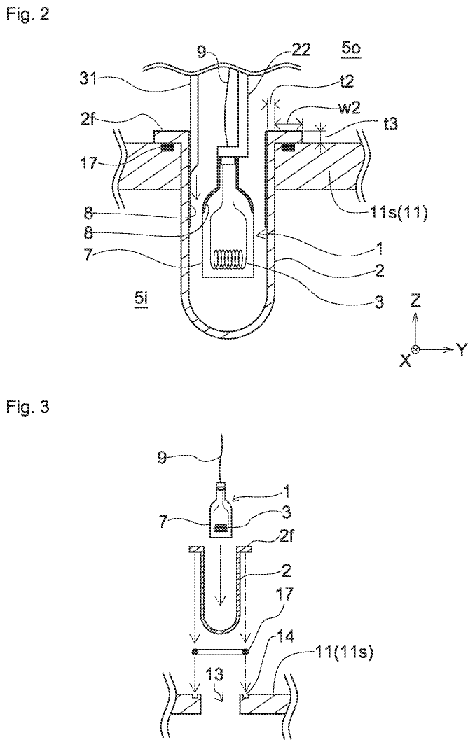

A thickness t2 (see FIG. 2) of each of the light transmissive containers 2 is set according to the pressure capacity required of each of the light transmissive containers 2. The thickness t2 may be 1 mm or more, and is preferably 2 mm or more. However, as described above, if the thickness t2 is too large, there is a fear that irradiance is reduced due to an increase in separation distance between the light emitting element and the substrate or an increase in light transmission loss. The thickness t2 may be 5 mm or less, and is preferably 3 mm or less.

Electric power is supplied to the light emitting element 3 through the power feeder 9. The power feeder 9 is electrically connected to a control unit (not shown) so that lighting of the light emitting element 3 is controlled by the control unit. The light emitting element 3 in each of the heating sources 1 is located inside the housing 11. Since the light emitting element 3 is located inside the housing 11, light emitted from the light emitting element 3 is less likely to be blocked by the housing 11.

The light emitting element 3 of the present embodiment is a filament. When electric power is supplied to the light emitting element 3, the light emitting element 3 emits light. Light emitted from the light emitting element 3 transfers heat energy to the substrate W1. As the light, for example, at least one selected from among infrared light, visible light, and ultraviolet light is emitted. The material of the filament is not limited, but for example, tungsten is appropriately used. The light emitting element 3 is not limited to a filament. For example, the light emitting element 3 may be a solid-state light source such as an LED or an LD. One heating source 1 may have a single light emitting element 3 or a plurality of light emitting elements 3.

### [Details of Heating Sources and Light Transmissive Containers]

FIG. 2 is an enlarged view of one light transmissive container 2 and its peripheral area. FIG. 3 is an exploded view of the area shown in FIG. 2. Each of the light transmissive containers 2 of the present embodiment has a cylindrical shape having a hemispherical bottom. However, each of the light transmissive containers 2 may have a rectangular tube shape, and the bottom thereof may be flat. The light transmissive containers 2 may be made of a material that has a high transmittance for light extracted from the light emitting element. When ultraviolet light is extracted from the light emitting element, the light transmissive containers 2 are preferably made of quartz that allows ultraviolet light to pass through it easily.

Each of the light transmissive containers 2 has, at its end away from the bottom, a flange 2f that protrudes from the cylinder. The flange 2f is formed to protrude from the cylinder along an XY plane and around the entire circumference (360 degrees) of the cylinder. A width w2 (seen FIG. 2) of the flange 2f may be 5 mm or more and 10 mm or less. The light transmissive containers 2 may be different from each other in the width w2 of the flange 2f. A thickness t3 (see FIG. 2) of the flange 2f may be 2 mm or more and 10 mm or less. The thickness t3 of the flange 2f may be the same as or different from the thickness t2 of each of the light transmissive containers 2.

The flange 2f has a seal 17 to achieve hermetic sealing between the outer surface of the housing 11 and the flange 2f. When each of the light transmissive containers 2 is inserted into a hole 13 (see FIG. 3) in (the ceiling 11s of) the housing 11, hermetic sealing between the outer surface of the ceiling 11s of the housing 11 and the flange 2f is achieved. This makes it possible to prevent a gas in the outside 5o of the vacuum chamber 5 from flowing into the inside 5i of the vacuum chamber 5. In the present embodiment, a groove 14 (see FIG. 3) to insert the seal 17 is provided in the outer surface of the housing 11. The flange 2f may have a groove to insert the seal 17. The seal 17 is not limited, but for example, a gasket O ring may be used. It should be noted that the flange 2f is one means to easily achieve hermetic sealing between the housing 11 and each of the light transmissive container 2, and therefore the flange 2f is not an essential component for each of the light transmissive containers 2.

The optical heating apparatus 100 has a plurality of nozzles 31 (see FIG. 1 or FIG. 2) to supply cooling fluid CF between the light transmissive containers 2 and the heating sources 1. In the optical heating apparatus 100 of the present embodiment, one nozzle 31 is provided for one light transmissive container 2. The tips of the nozzles 31 are inserted in the light transmissive containers 2. A pipe 30 for the cooling fluid CF is branched and connected to the nozzles 31 (see FIG. 1). The cooling fluid CF ejected from the nozzles 31 surrounds the heating sources 1 to cool the heating sources 1 (see FIG. 2). As the cooling fluid CF, air or an inert gas (e.g., nitrogen) is appropriately used.

Referring to FIG. 2, each of the heating sources 1 has an envelope 7 to enclose the light emitting element 3. Each of the heating sources 1 has a reflector 8 at part of the inside of the envelope 7. Each of the light transmissive containers 2 also has the reflector 8 on its inner surface. The reflector 8 is provided for at least one of the purposes of orienting light from the heating source 1 (light emitting element 3) toward the substrate W1 and the purpose of preventing light from the heating source 1 from traveling toward the other heating sources 1 and the other light transmissive containers 2 in which the other heating sources 1 are inserted. The former purpose is intended to increase the use efficiency of light. The latter purpose is intended to prevent heating of the other heating sources 1 and the other light transmissive containers 2.

The reflector 8 is, for example, a reflective film made of Al, Au, Ag, ceramic, or the like. The ceramic used for the reflector 8 is alumina (Al₂O₃) or titania (TiO₂). The reflective film may be formed by vapor deposition, coating, or a film forming technique using a chemical method. In the present embodiment, the envelope 7 has the reflector 8 at part of the inside thereof. However, the envelope 7 may have the reflector 8 at part of the outside thereof. It should be noted that each of the light transmissive containers 2 may have the reflector 8 on the outer surface thereof.

In consideration of the purpose of preventing light from the heating source 1 from traveling toward the other heating sources 1 and the other light transmissive containers 2 in which the other heating sources 1 are inserted, each of the heating sources 1 may have, at part of the inside of the envelope 7, a light shield to absorb or scatter light instead of the reflector 8. Each of the light transmissive containers 2 may have, on the inner surface thereof, a light shield instead of the reflector 8. The light shield may either be a light shielding film or a light shielding plate. It should be noted that each of the light transmissive containers 2 may have the light shield on the outer surface thereof.

### [Adjustment of Distances Between Each Heating Source and Substrate]

Referring to FIG. 1 again, the optical heating apparatus 100 has a support 21 to support the plurality of heating sources 1. The support 21 supports a plurality of support bars 22. Each of the support bars 22 supports each of the heating sources 1. The optical heating apparatus 100 has a distance adjuster 20 to change distances d1 (details will be described later) between each of the light emitting elements 3 and the substrate W1. The distance adjuster 20 of the present embodiment includes a screw portion 20s provided in each of the support bars 22 and a knob 20k to rotate each of the support bars 22 around a direction in which the support bar 22 extends. The screw portion 20s is formed by external thread cutting of each of the support bars 22. The screw portion 20s is inserted into a hole in the support 21 and engaged with an internal screw portion in the hole. The knob 20k is provided at the end of each of the support bars 22 different from the end connected to the heating source 1. When an operator rotates the knob 20k, the support bar 22 is rotated so that the support bar 22 and the heating source 1 are displaced in the Z direction. As a result, the distance between each of the heating sources 1 (each of the light emitting elements 3) and the substrate W1 is adjusted. It should be noted that when all the heating sources 1 need to be displaced in the Z direction, the support 21 may be displaced in the Z direction.

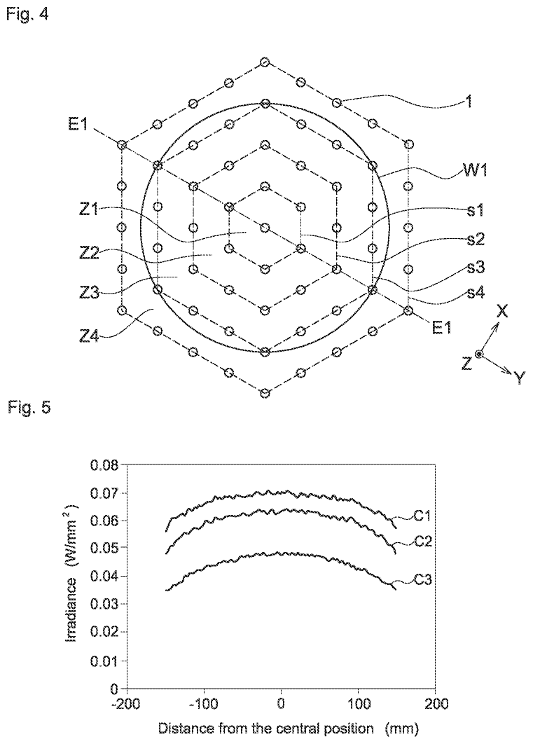

FIG. 4 is a diagram showing a positional relationship between the plurality of heating sources 1 of the optical heating apparatus 100 and the substrate W1. FIG. 4 shows only the heating sources 1, the substrate W1, and virtual lines described later when viewed from the upper side (+Z side) toward the lower side (−Z side) of the optical heating apparatus 100. Each of a total of 61 heating sources 1 is indicated by a small open circle. As shown in FIG. 4, the heating sources 1 are arranged in a honeycomb structure form. The “honeycomb structure form” refers to a form in which the heating sources 1 are disposed at the vertex positions of regular hexagons different from each other in size or at positions on the sides of the regular hexagons.

The arrangement in the honeycomb structure form of the present embodiment will be described in detail. Dashed lines in FIG. 4 are virtual lines for sorting the heating sources 1. A plurality of regular hexagons (s1 to s4) different from each other in size are drawn by the virtual lines. A total of seven heating sources 1, which are disposed on the smallest regular hexagon s1 and at the center of the substrate W1, belong to a zone Z1. Twelve heating sources 1, which are disposed on the regular hexagon s2 located outside the regular hexagon s1, belong to a zone Z2. Eighteen heating sources 1, which are disposed on the regular hexagon s3 located outside the regular hexagon s2, belong to a zone Z3. It should be noted that the vertices of the regular hexagon s3 overlap with the edge of the substrate W1 having a diameter of 300 mm. Twenty-four heating sources 1, which are disposed on the regular hexagon s4 located outside the regular hexagon s3, belong to a zone Z4. The twenty-four heating sources 1 disposed on the regular hexagon s4 are all disposed outside the substrate W1. A sectional view taken along a line E1-E1 shown in FIG. 4 corresponds to FIG. 1. In FIG. 1, the heating sources 1 are shown in such a manner that which of the zones (Z1 to Z4) each of the heating sources 1 belongs to is clear.

### [Effect Obtained by Distance Adjustment]

FIG. 5 is a graph showing a relationship between a distance from the central position of the substrate W1 and irradiance. This graph was obtained by an optical simulation. The conditions of the simulation are set as follows.
Arrangement of heating sources 1: arrangement shown in FIG. 4
Number of heating sources 1: 61
Output (power consumption) of each heating source 1: 1 W
Size of substrate W1: 300 mm in diameter

A curved line C1 is a curved line at the time when the distances d1 (see FIG. 1) from the position of center of gravity of each of the light emitting element 3 to the surface of the substrate W1 are all 43.75 mm. A curved line C2 is a curved line at the time when the distances d1 are 63.75 mm. A curved line C3 is a curved line at the time when the distances d1 are 113.75 mm.

As can be seen from. FIG. 5, when the distances d1 reduce, the irradiance increases. It can also be seen that as the distance from the center of the substrate W1 increases, the irradiance reduces, and the in-plane irradiance variation of the substrate W1 increases. When the in-plane irradiance variation increases, the entire substrate W1 cannot evenly be heat-treated.

It is considered that there are two major methods to reduce the in-plane irradiance variation. The first method is one in which the distances d1 (separation distances between the position of center of gravity of each of the light emitting elements 3 and the substrate W1) are changed, that is, the distance d1 is increased as the distance from the center of the substrate W1 to each of the light emitting elements 3 decreases. The second method is one in which the outputs of the light emitting elements 3 are changed, that is, the output of each of the light emitting elements 3 is reduced as the distance from the center of the substrate W1 to the light emitting element 3 decreases.

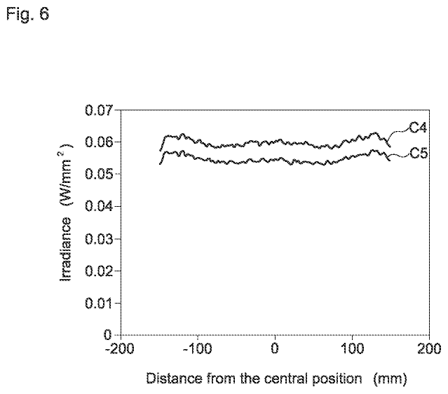

The result of the comparison between the first method and the second method is shown in FIG. 6. FIG. 6 is a graph showing a relationship between a distance from the central position of the substrate W1 and irradiance at the time when the in-plane irradiance variation is reduced by each of the methods.

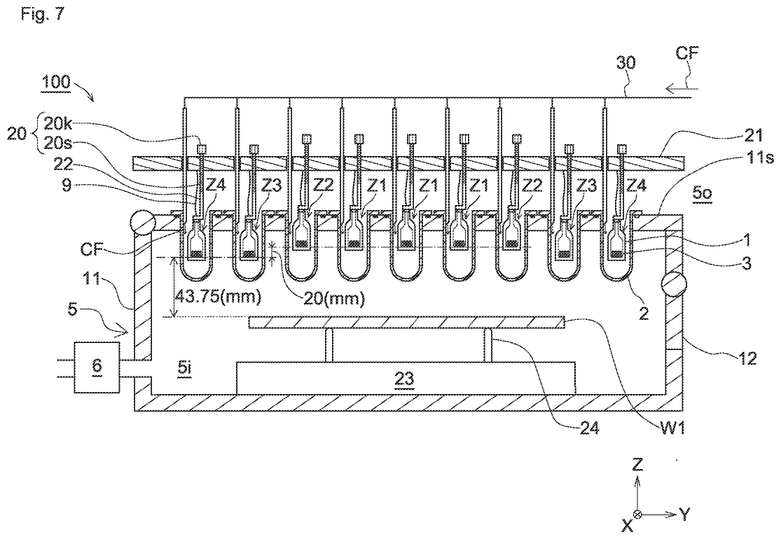

A curved line C4 in the graph is a result at the time when the in-plane irradiance variation is reduced by the method in which the distances d1 between each of the heating sources 1 and the substrate W1 are changed on an individual basis. The conditions at the time when the curved line C4 is obtained are set as follows. FIG. 7 is a diagram of the optical heating apparatus 100 at the time when the distances d1 are set as follows.
Arrangement of heating sources 1: arrangement shown in FIG. 4
Number of heating sources 1: 61
Size of substrate W1: 300 mm in diameter
Output of each heating source: 100% (maximum output)
Distances d1 between each light emitting element 3 and substrate W1:
   Distance d1 in zone Z1: 63.75 mm (larger than those in zones Z3 and Z4 by 20 mm)
   Distance d1 in zone Z2: 63.75mm (larger than those in zones Z3 and Z4 by 20 mm)
   Distance d1 in zone Z3: 43.75 mm
   Distance d1 in zone Z4: 43.75 mm

A curved line C5 in the graph is a result at the time when the in-plane irradiance variation is reduced by the method in which the outputs of the light emitting elements 3 of the heating sources 1 are changed on an individual basis. The conditions at the time when the curved line C5 is obtained are set as follows.
Arrangement of heating sources 1: arrangement shown in FIG. 4
Number of heating sources 1: 61
Size of substrate W1: 300 mm in diameter
Distances d1 between each light emitting element 3 and substrate W1: all 43.75 mm
Outputs of heating sources 1:
   Output in zone Z1: 75% of rated maximum output
   Output in zone Z2: 65% of rated maximum output
   Output in zone Z3: 100% (rated maximum output of light emitting element 3)
   Output in zone Z4: 100% (rated maximum output of light emitting element 3)

As can be seen from the curved line C4 and the curved line C5, both the first method and the second method can reduce the in-plane irradiance variation. However, as a whole, the irradiance of the curved line C4 is higher than that of the curved line C5. That is, it can be seen that in order to reduce the in-plane irradiance variation, adjusting the distances d1 between each of the heating sources 1 and the substrate W1 on a zone-by zone basis is more preferred than adjusting the outputs of the heating sources 1 on a zone-by-zone basis because the irradiance is further improved as a whole.

The above methods are performed by dividing the plurality of heating sources 1 into a plurality of zones to which they belong and adjusting the distances d1 or the outputs of the heating sources 1 on a zone-by-zone basis. However, it is expected that a similar tendency is indicted even when each of the above methods is performed by adjusting the distances d1 or the outputs of the heating sources 1 on an individual basis. That is, in order to reduce the in-plane irradiance variation, adjusting the distances d1 between each of the heating sources 1 and the substrate W1 on an individual basis is more preferred than adjusting the outputs of the heating sources 1 on an individual basis because the irradiance is further improved as a whole.

Therefore, when the optical heating apparatus 100 includes the distance adjuster 20 to change the distances d1 between each of the light emitting element 3 and the substrate W1, the irradiance can be improved as a whole while the in-plane irradiance variation is reduced by adjusting the distances d1 between each of the heating sources 1 and the substrate W1 on an individual basis.

### Second Embodiment

A second embodiment of the optical heating apparatus will be described by focusing on differences from the first embodiment. The description of the same points as in the first embodiment will not be repeated. The same applies to third and later embodiments. FIG. 8 is a diagram for illustrating a major part of the second embodiment of the optical heating apparatus. Each of the heating sources 1 of the optical heating apparatus of the present embodiment is provided with the reflector 8 on the outside of the envelope 7. The reflector 8 is not in contact with the envelope 7. The reflector 8 of the present embodiment has an almost conical shape having a hole at its center and is configured to surround the envelope 7. The reflector 8 orients light from the light emitting element 3 toward the substrate W1. This improves the use efficiency of light. The reflector 8 shown in FIG. 8 has a straight (flat) reflecting surface, but the reflecting surface of the reflector 8 may be parabolic or elliptical in shape.

### Third Embodiment

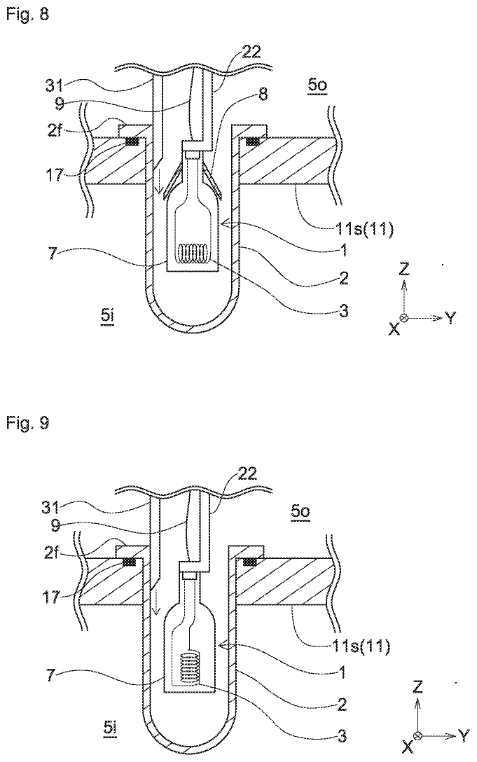

FIG. 9 is a diagram for illustrating a major part of a third embodiment of the optical heating apparatus. The light emitting element 3 of the present embodiment is a filament spirally wound around an axis extending in the Z direction that is a vertical direction (see FIG. 9). It should be noted that the filament constituting the light emitting element 3 in the first embodiment is spirally wound around an axis extending in the Y direction parallel to the horizontal direction (see FIG. 2). The direction in which the wound filament extends may either be the horizontal direction or a direction orthogonal to the horizontal direction. The filament wound in such a manner as shown in FIG. 9 tends to strongly emit light in the horizontal direction (XY direction), and the filament wound in such a manner as shown in FIG. 2 tends to strongly emit light in the vertical direction (Z direction). Therefore, from the viewpoint of efficiently using light, it is preferred that the filament is spirally wound along the horizontal direction as shown in FIG. 2.

### Fourth Embodiment

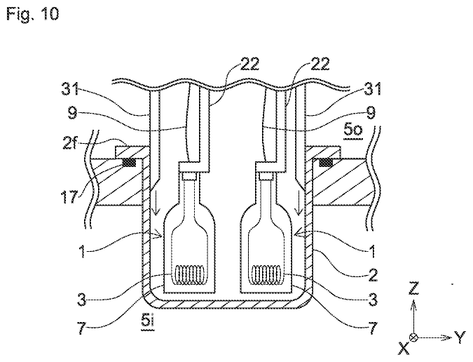

FIG. 10 is a diagram for illustrating a major part of a fourth embodiment of the optical heating apparatus. In the optical heating apparatus of the present embodiment, two heating sources 1 are inserted in one light transmissive container 2. The optical heating apparatus of the present embodiment includes a plurality of light transmissive containers 2 each of which accommodates two heating sources 1. Such an optical heating apparatus is advantageous in that its structure can be simplified as compared to a case where one heating source 1 is inserted in one light transmissive container 2. Further, in the present embodiment, the light transmissive containers 2 are reduced in size as compared to a single light transmissive container that accommodates all the heating sources 1. Therefore, the light transmissive containers 2 of the present embodiment can be reduced in thickness as compared to the single light transmissive container that accommodates all the heating sources 1. In the present embodiment, the light transmissive containers 2 have a flat base.

### Fifth Embodiment

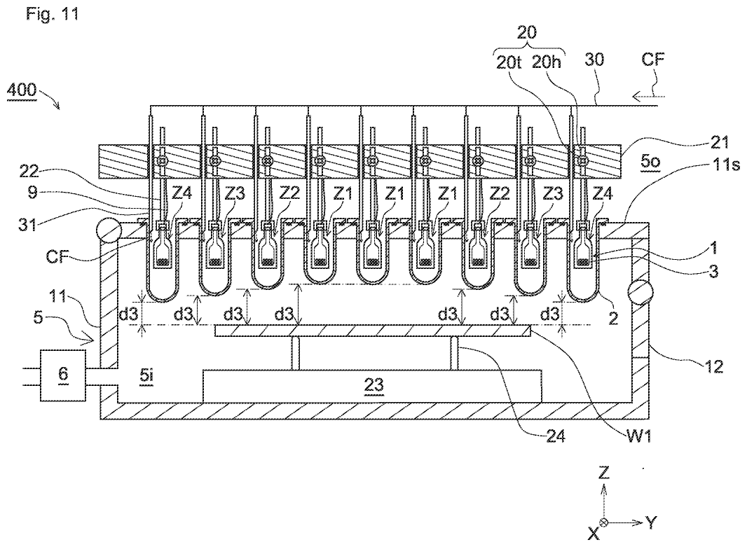

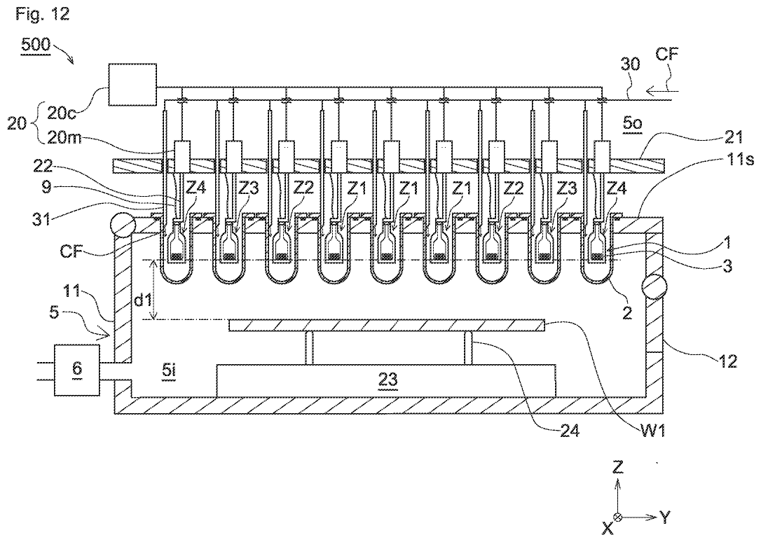

FIG. 11 is a diagram showing a fifth embodiment of the optical heating apparatus. In an optical heating apparatus 400, the lengths of the light transmissive containers 2 in the Z direction are not uniform. Therefore, distances d3 between the lowermost end of each of the light transmissive containers 2 and the substrate W1 in the Z direction are not uniform. The distances d3 are set on a zone-by-zone basis (Z1 to Z4). The longer the length of the light transmissive container 2, the greater the displacement range of the heating source 1. In the present embodiment, the distances d3 are gradually reduced by using the light transmissive containers 2 whose lengths increase toward the outermost zone. This increases the displacement range of the heating source 1 toward the outermost zone.

In the present embodiment, a modification of the distance adjuster 20 is shown. Each of the support bars 22 is inserted in a through hole in the support 21. Each of the support bars 22 has a screw 20t. The support 21 has a hole 20h in which the screw 20t is slidable. When an operator tightens the screw 20t, the support bar 22 is pressed against the support 21 and fixed to the support 21 by frictional force between them. This makes it possible to fix the light emitting element 3 in a state where the distance between the light emitting element 3 and the surface of the substrate W1 is adjusted to a desired value.

### Sixth Embodiment

FIG. 12 is a diagram showing a sixth embodiment of the optical heating apparatus. The distance adjuster 20 of an optical heating apparatus 500 includes a drive unit 20m to displace the light emitting element 3 (heating source 1) in the Z direction and a control unit 20c to control the drive unit 20m. The control unit 20c displaces the light emitting element 3 according to a separation distance between a position on the substrate W1 opposed to the light emitting element 3 (heating source 1) and the center of the substrate W1.

The control unit 20c adjusts the distances d1 between each of the heating sources 1 and the substrate W1 on the basis of an irradiance measurement result. The drive unit 20m may be constituted from an air cylinder or an electromagnetic actuator. The irradiance measurement result is obtained by, for example, measuring irradiance at each position in the surface of the substrate W1 with the use of an irradiance sensor not shown.

The embodiments and the modifications thereof have been described above. The present invention is not limited to the above embodiments and the modifications thereof, and the above embodiments and modifications may appropriately be combined or further be modified.

The distance adjuster 20 is not limited to those described above. A further modification of the distance adjuster 20 may be one intended not to change all the distances d1 between each of the heating sources 1 and the substrate W1 but to change some of the distances d1 between each of the heating sources 1 and the substrate W1.

A further modification of the light transmissive container 2 may have, on the inside or outside thereof, an optical component (e.g., a lens) to scatter or distribute light.

In the above embodiments, the arrangement in the honeycomb structure form is disclosed in which the heating sources 1 are disposed at the vertex positions of regular hexagons. However, such an arrangement is an example, and another arrangement may be adopted.

The optical heating apparatus of each of the embodiments is applied to a vacuum chamber into and out of which a substrate is to be taken by a transfer arm, may be applied to a vacuum chamber into and out of which a substrate is to be taken in such a manner that the substrate is moved on a plurality of rollers.

What is claimed is:

1. An optical heating apparatus comprising:
a plurality of heating sources to optically heat a substrate;
a plurality of light transmissive containers in which the heating sources are inserted and which transmit light from the heating sources; and
a vacuum chamber including a housing having an inside in which the substrate can be placed, the housing having a hole to insert the plurality of light transmissive containers at a position opposed to the substrate placed in the inside,
wherein each of the plurality of heating sources has at least one light emitting element, and
the plurality of heating sources emit light toward the substrate placed in the vacuum chamber through the plurality of light transmissive containers inserted in the hole and protruding from the housing toward the inside.

2. The optical heating apparatus according to claim 1, wherein
each of the light transmissive containers has a flange that is in contact with an outer surface of the housing, and
the flange has a seal to achieve hermetic sealing between the flange and the outer surface.

3. The optical heating apparatus according to claim 1, wherein the respective heating sources are inserted in the different light transmissive containers.

4. The optical heating apparatus according to claim 1, wherein the light emitting element of at least one of the heating sources is located inside the housing.

5. The optical heating apparatus according to claim 1, wherein the light emitting element is a filament.

6. The optical heating apparatus according to claim 1, comprising a distance adjuster to adjust a distance between the light emitting element of each of the heating sources and the substrate.

7. The optical heating apparatus according to claim 2, comprising a distance adjuster to adjust a distance between the light emitting element of each of the heating sources and the substrate.

8. The optical heating apparatus according to claim 3, comprising a distance adjuster to adjust a distance between the light emitting element of each of the heating sources and the substrate.

9. The optical heating apparatus according to claim 4, comprising a distance adjuster to adjust a distance between the light emitting element of each of the heating sources and the substrate.

10. The optical heating apparatus according to claim 5, comprising a distance adjuster to adjust a distance between the light emitting element of each of the heating sources and the substrate.

11. The optical heating apparatus according to claim 6, wherein
the distance adjuster includes a drive unit to displace the light emitting element and a control unit to control the drive unit, and
the control unit displaces the light emitting element according to a separation distance between a center of the substrate and a position on the substrate opposed to the light emitting element.

12. The optical heating apparatus according to claim. 7, wherein
the distance adjuster includes a drive unit to displace the light emitting element and a control unit to control the drive unit, and
the control unit displaces the light emitting element according to a separation distance between a center of the substrate and a position on the substrate opposed to the light emitting element.

13. The optical heating apparatus according to claim 8, wherein
the distance adjuster includes a drive unit to displace the light emitting element and a control unit to control the drive unit, and
the control unit displaces the light emitting element according to a separation distance between a center of the substrate and a position on the substrate opposed to the light emitting element.

14. The optical heating apparatus according to claim 9, wherein
the distance adjuster includes a drive unit to displace the light emitting element and a control unit to control the drive unit, and
the control unit displaces the light emitting element according to a separation distance between a center of the substrate and a position on the substrate opposed to the light emitting element.

15. The optical heating apparatus according to claim 10, wherein
the distance adjuster includes a drive unit to displace the light emitting element and a control unit to control the drive unit, and
the control unit displaces the light emitting element according to a separation distance between a center of the substrate and a position on the substrate opposed to the light emitting element.

16. The optical heating apparatus according to claim 1, wherein each of the light transmissive containers has a reflector or a light shield to reflect or shield light traveling toward the other light transmissive containers.

17. The optical heating apparatus according to claim 16, wherein the reflector or the light shield is formed on an inner surface of each of the light transmissive containers.

18. The optical heating apparatus according to claim 1, comprising a reflector having a parabolic shape or an elliptical shape to orient light emitted from the light emitting element toward the substrate.

19. The optical heating apparatus according to claim 1, comprising a nozzle to supply cooling fluid between the light transmissive containers and the heating sources.
